(19) United States
(12) Patent Application Publication
(10) Pub. No.: US 2024/0222938 A1
(43) Pub. Date: Jul. 4, 2024

(54) MANUFACTURING OF SURFACE EMITTING LASERS INCLUDING AN INTEGRATED METASTRUCTURE

(71) Applicant: NILT Switzerland GmbH, Horgen (CH)

(72) Inventors: Maksim Zalkovskij, Copenhagen (DK); Brian Bilenberg, Ølstykke (DK); Theodor Nielsen, Copenhagen (DK); James Eilertsen, Skodsborg (DK)

(21) Appl. No.: 18/289,168

(22) PCT Filed: May 4, 2022
(86) PCT No.: PCT/EP2022/062002

§ 371 Date: Nov. 1, 2023

Related U.S. Application Data
(60) Provisional application No. 63/184,459, filed on May 5, 2021.

(51) Int. Cl. H01S 5/183

(52) U.S. Cl. CPC H01S 5/18386; H01S 5/18311; H01S 5/18347; H01S 5/18377

(57) ABSTRACT

The manufacture of surface emitting lasers that include an optical metastructure are described. For example, in accordance with some implementations, a method includes providing a sequence of semiconductor layers and processing the sequence of semiconductor layers to form an upper reflector disposed over an active layer, the active layer being disposed over a lower reflector, and the lower reflector layer being disposed over a substrate. The semiconductor layers in which the upper reflector is formed include one or more outer semiconductor layers, and the method includes forming a metastructure in the one or more outer semiconductor layers.

### FIELD OF THE DISCLOSURE

The present disclosure relates to the manufacture of surface emitting lasers that include a metastructure.

### BACKGROUND

A vertical cavity surface emitting laser (VCSEL) is a type of semiconductor laser diode having laser beam emission perpendicular from the top surface. In some processes, VCSELs can be tested at several stages throughout the manufacturing process to check for material quality and processing issues. Additionally, because VCSELs emit the beam perpendicular to the active region of the laser, many VCSELs can be processed simultaneously, for example, on a gallium arsenide or other wafer.

A typical VCSEL includes two distributed Bragg reflector (DBR) mirrors parallel to the wafer surface with an active region consisting of one or more quantum wells for the laser light generation in between. The planar DBR mirrors can be composed of layers with alternating high and low refractive indices. Each layer has a thickness of a quarter of the laser wavelength in the material, yielding very high intensity reflectivities.

### SUMMARY

The present disclosure describes the manufacture of surface emitting lasers (e.g., VCSELs) that include an optical metastructure. Formation of the metastructure can be integrated into the fabrication for the surface emitting laser in a compatible manner.

In one aspect, for example, the present disclosure describes a method that includes providing a sequence of semiconductor layers and processing the sequence of semiconductor layers to form an upper reflector disposed over an active layer, the active layer being disposed over a lower reflector, and the lower reflector layer being disposed over a substrate. The semiconductor layers in which the upper reflector is formed include one or more outer semiconductor layers, and the method includes forming an optical metastructure in the one or more outer semiconductor layers.

Some implementations include one or more of the following features. For example, in some implementations, the metastructure is operable to provide a beam shaping function. In some implementations, the metastructure is further operable as a partially transmissive optical reflector.

In some implementations, the method includes etching portions of the sequence of semiconductor layers that form the lower reflector, the active layer, and the upper reflector to form a mesa structure. In some cases, the metastructure is formed prior to forming the mesa structure. In other cases, the metastructure is formed after forming the mesa structure.

Other aspects, features and advantages will be readily apparent from the following detailed description, the accompanying drawings, and the claims.

### BRIEF DESCRIPTION OF THE DRAWINGS

FIG. 1 illustrates an example of a surface emitting laser that includes a metastructure.

FIGS. 2 through 8 illustrate various stages in the fabrication of the surface emitting laser of FIG. 1.

FIGS. 9A through 9I illustrate various steps in a first example process for forming the metastructure.

FIGS. 10A through 10J illustrate various steps in a second example process for forming the metastructure.

FIGS. 11A through 11I illustrate various steps in a third example process for forming the metastructure.

FIGS. 12A through 12G illustrate various steps in a fourth example process for manufacturing the metastructure.

FIGS. 13A through 13I illustrate various steps in a fifth example process for manufacturing the metastructure.

FIGS. 14A through 14I illustrate various steps in a sixth example process for manufacturing the metastructure.

FIGS. 15A through 15G illustrate various steps in a seventh example process for manufacturing the metastructure.

FIGS. 16A through 16K illustrate various steps in an eighth example process for manufacturing the metastructure.

### DETAILED DESCRIPTION

The present disclosure describes the manufacture of VCSELs that include a metastructure, which refers to a surface with distributed small structures (e.g., meta-atoms) arranged to interact with light in a particular manner. For example, a metastructure can include a surface with a distributed array of nanostructures or other meta-atoms. The nanostructures may, individually or collectively, interact with light waves. For example, the nanostructures or other meta-atoms may change a local amplitude, a local phase, or both, of an incoming light wave.

When meta-atoms (e.g., nanostructures) of a metastructure are in a particular arrangement, the metastructure may act as an optical element such as a lens, lens array or other beam shaping element. In some instances, metastructure may perform optical functions that are traditionally performed by reflective optical elements.

As described in greater detail below, techniques for forming metastructures are integrated into the manufacture of VCSELs. Depending on the implementation, the metastructure can provide, for example, a beam shaping function (e.g., focusing of light) or serve as a largely reflective, but partially transmissive, mirror. For example, in some implementations, the metastructure can be configured so that for a particular wavelength (or wavelength range), the metastructure is at least 99% reflective, and partially transmissive (e.g., approximately 1% transmissive). In some instances, the metastructure can provide both functions. That is, in some implementations, the metastructure can provide a beam shaping function and also provide a largely reflective surface that also is partially transmissive.

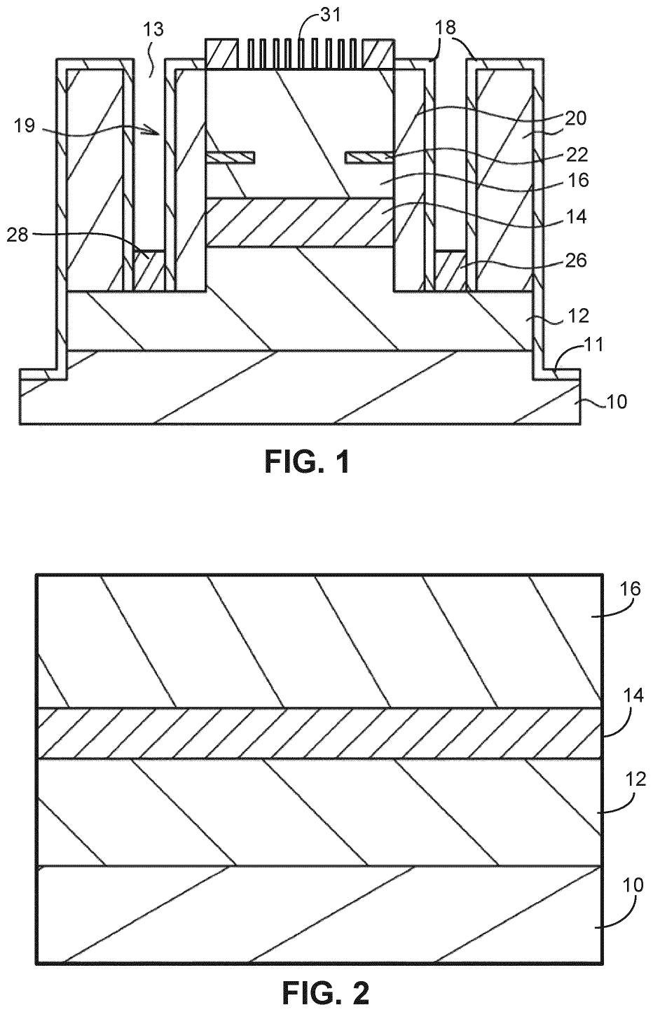

FIG. 1 illustrates an example of a surface emitting laser (e.g., a VCSEL) that includes a metastructure 31. In the illustrated example, the VCSEL includes a substrate 10, a lower reflector (e.g., a DBR) layer 12, an active layer 14, an upper reflector layer 16, an insulating film 18, and electrodes 26, 28. The substrate 10 is a semiconductor substrate formed, for example, of semi-insulating gallium arsenide (GaAs) The lower reflector layer 12, the active layer 14, and the upper reflector layer 16 are stacked in this order on the substrate 10, and can be composed of semiconductor layers that constitute a mesa 19, which is surrounded by a groove 13. Details of the VCSEL may differ in some implementations.

Each of the lower and upper reflector layers 12, 16 may be composed, respectively, of multilayer semiconductor films. For example, the lower reflector layer 12 can be composed of stacked n-type AlGaAs films whose compositions alternate and have respective optical thicknesses of λ/4, where λ is the operational wavelength of light. The lower reflector layer 12 also includes a contact layer that is in contact with the electrode 26. Other semiconductor materials may be used in some implementations.

The active layer 14 can be composed, for example, of AlGaAs and AlInGaAs. The active layer has a multiple quantum well (MQW) structure in which quantum well layers and barrier layers are alternately stacked, and has an optical gain. Other semiconductor materials may be used in some implementations.

The upper reflector layer 12 can include, for example, stacked p-type AlGaAs films whose compositions alternate and have respective optical thicknesses of λ/4, where λ is the operational wavelength of light. The upper reflector layer 16 also includes a contact layer that is in contact with the electrode 28. Other semiconductor materials may be used in some implementations.

The metastructure 31 can be formed in one or more outer semiconductor layers of the upper reflector layer 16. The one or more outer semiconductor layers in which the metastructure is formed can be composed, for example, of GaAs. Other semiconductor materials may be used in some implementations. In some cases, the metastructure 31 is configured to shape or direct transmitted light, and the underlying sublayers of the upper reflector layer 16 provide the largely reflective, partially transmissive optical functions. In some cases, the metastructure 31 also is configured to be largely reflective (and partially transmissive), and also is configured to shape or direct the transmitted light.

Part of the upper reflector layer 16 is selectively oxidized, to form a current narrowing layer 22, which is disposed at the edge of the upper reflector layer 16, and is not formed in the central portion of the upper reflector layer 16. The unoxidized portion that is the central portion of the upper reflector layer 16 serves as a current path to allow efficient current injection. The VCSEL has a high-resistance region 20 on the outer side of the current narrowing layer 22 and in the periphery of the mesa 19. The high-resistance region 20 is present in the upper reflector layer 16, the active layer 14, and an upper portion of the lower reflector layer 12.

In some instances, an insulating film 18 (e.g., a silicon nitride (SiN) film) covers the bottom surface of the groove 11, the surfaces of the high-resistance region 20, and the surfaces of the mesa 19, including the metastructure 31.

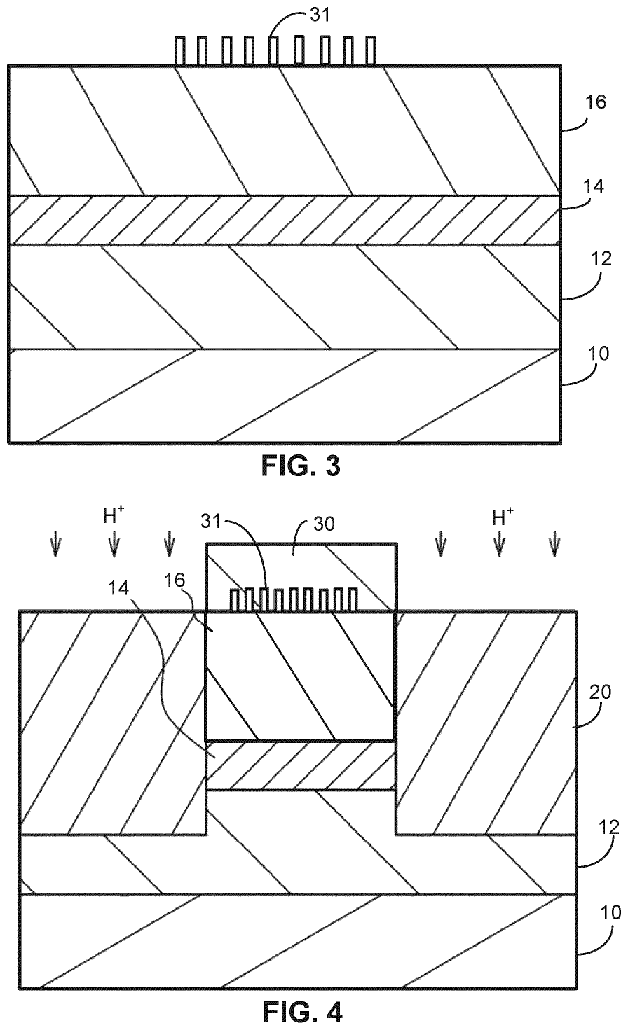

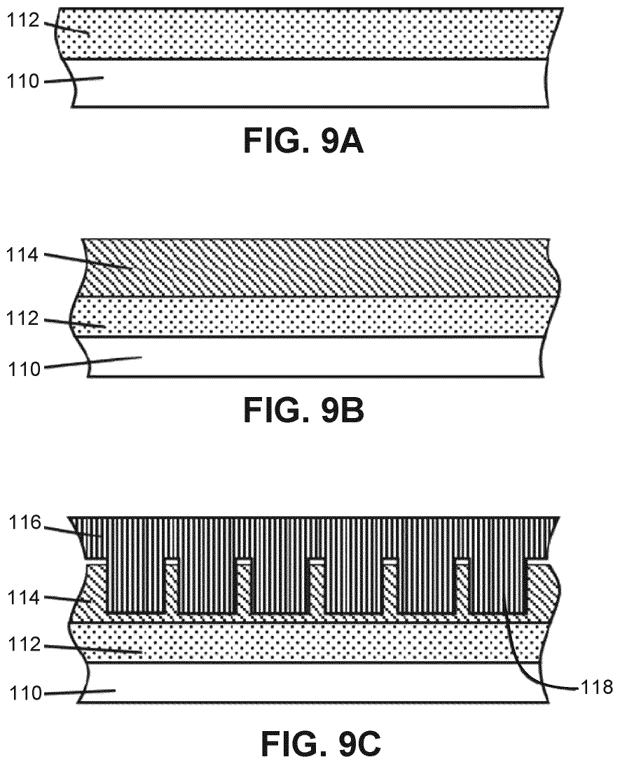

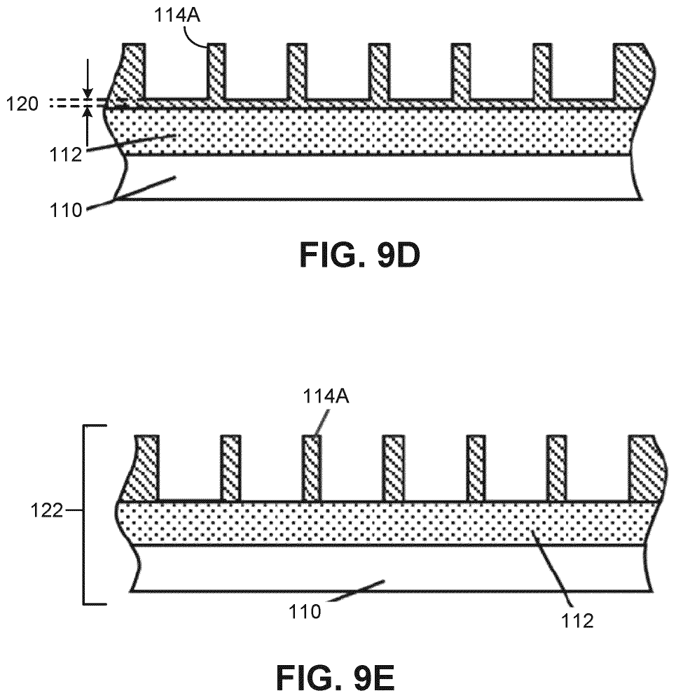

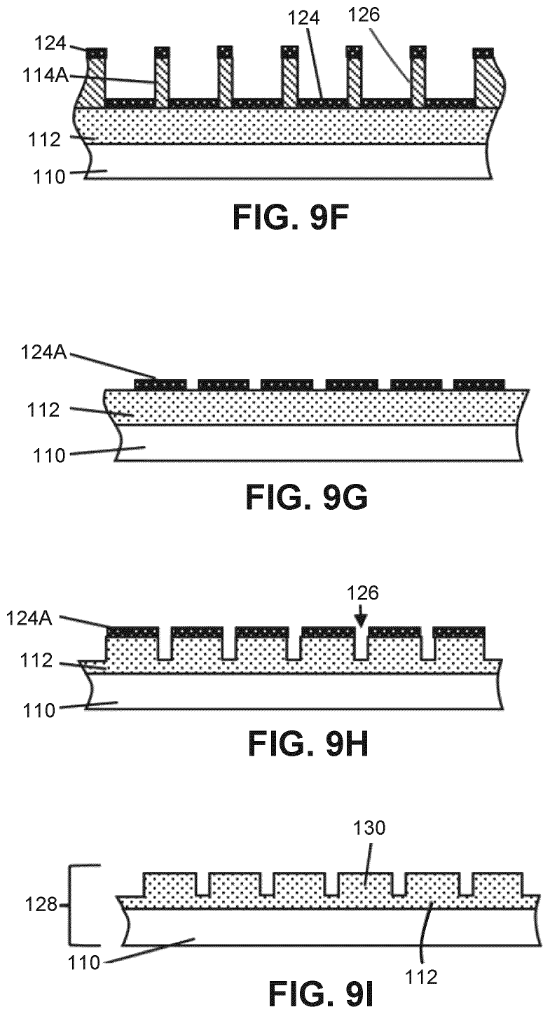

A method of manufacturing the surface emitting laser, including the metastructure 31, is described below. FIGS. 2 through 8 are cross-sectional diagrams showing an example method of manufacturing the surface emitting laser. As shown in FIG. 2, the lower reflector layer 12, the active layer 14, and the upper reflector layer 16 are epitaxially grown sequentially on the substrate 10, for example, by metal organic chemical vapor deposition (MOCVD), molecular beam epitaxy (MBE), or the like. The upper reflector layer 16 includes one or more outer layers in which the metastructure 31 subsequently is formed, as shown in FIG. 3. The metastructure 31 can be fabricated in any one of various ways that are compatible with the techniques for manufacturing the VCSEL. Details of various techniques for fabricating the metastructure 31 are described in connection with FIGS. 9 through 16.

Next, as shown in FIG. 4, resist patterning (e.g., masking, exposure and developing using standard photolithography) is performed on a photoresist 30 layer, which can be deposited, for example, by spin coating. As illustrated in FIG. 4, the photoresist 30 encases, and thus protects, the metastructure 31. After patterning the resist 30, ion injection is performed to form the high-resistance region 20. Following the ion injection, the remaining photoresist 30 is removed.

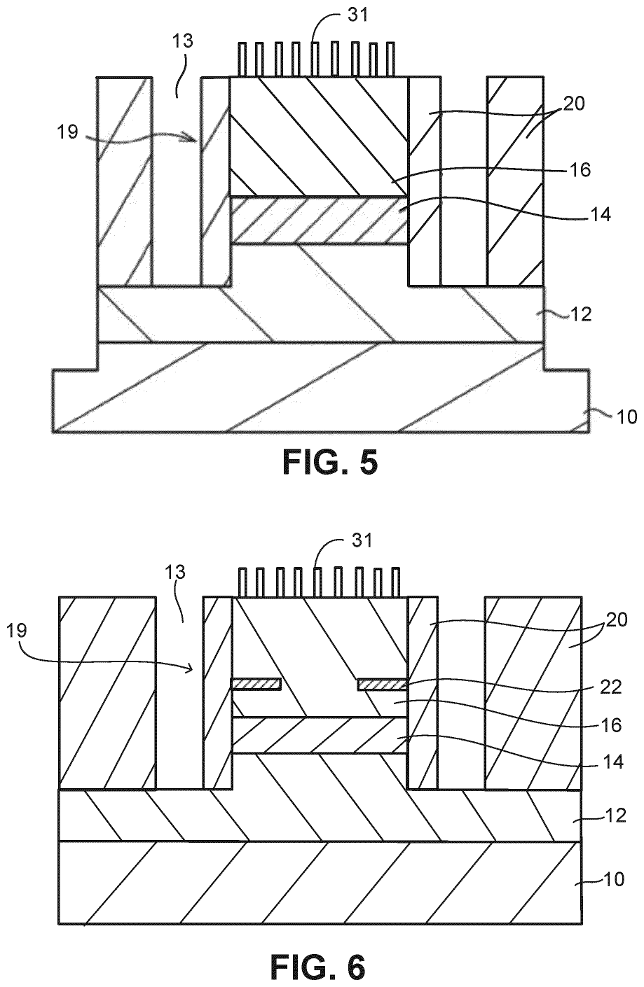

Next, as shown in FIG. 5, the mesa 19 is formed. For example, in some instances, dry etching can be performed on the high-resistance region 20 with an inductively coupled plasma reactive ion etching (ICP-RIE) device, to form the mesa 19. During the dry etch, the metastructure 31 and other portions of the VCSEL that are not be etched can be encased in photoresist (not shown) for protection.

Next, as shown in FIG. 6, heating (e.g., to about 400 degrees C.°) is performed, for example, in a water-vapor atmosphere. As a result, part of the upper reflector layer 16 is oxidized from the edge, thereby forming the current narrowing layer 22. The heating duration is set so that the current narrowing layer 22 has a predetermined width, and an unoxidized portion having a predetermined width remains on the inner side of the current narrowing layer 22. The metastructure 31 does not require protection (e.g., by photoresist) during the steam oxidation.

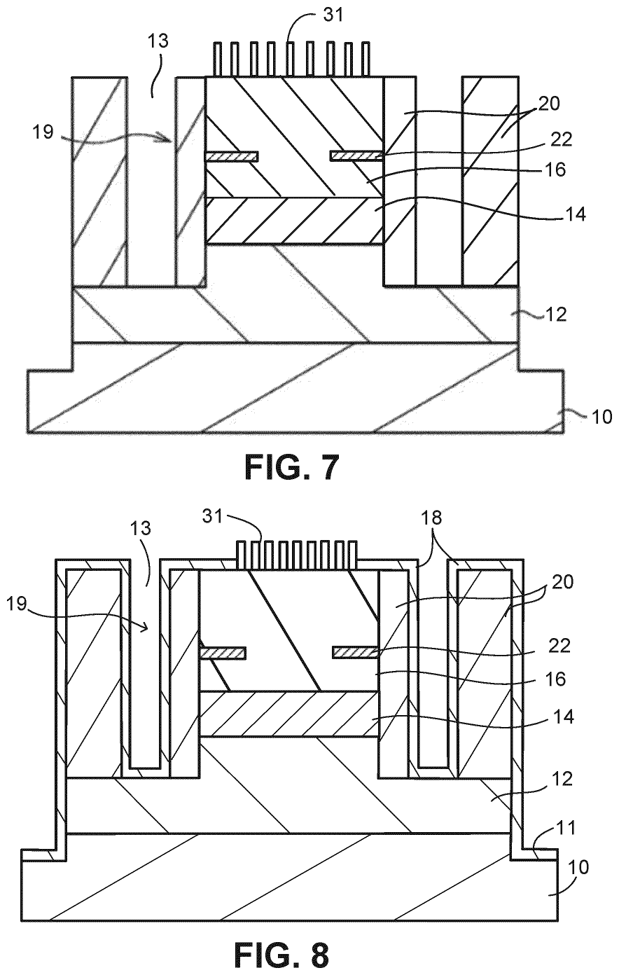

As shown in FIG. 7, dry etching then can be performed on the high-resistance region 20, the lower reflector layer 12, and part of the substrate 10, to form the groove 11. At this stage, the portions not to be subjected to the etching, such as the mesa 19 and the groove 13, are covered with a photoresist (not shown). After the etching, cleaning with pure water or the like may be performed in some implementations.

Next, as shown in FIG. 8, the insulating film 18 covering the wafer can be formed, for example, by plasma CVD or the like. Preferably, the film 18 is both highly electrically insulating and has a low refractive index. In some instances, the metastructure 31 is encased or completely embedded in the insulation film 18. In some instances, the insulation film 18 may be removed partially or completely.

Next, openings are formed in part of the insulating film 18. Resist patterning and vacuum vapor deposition then are performed to form the electrodes 26, 28 (see FIG. 1). After forming the electrodes, heat treatment (e.g., at a temperature of about 400 degrees C.°) can be conducted, for example, to cause ohmic contact between the electrodes and the semiconductor layers. Wiring lines or the like connecting to the electrodes 26 and 28 also may be formed, for example, by plating processing or the like.

The back surface of the substrate 10 can be polished with a back grinder, a lapping device, or the like, to reduce the wafer thickness. The wafer then can be diced so that individual surface emitting lasers are formed.

Various aspects of the VCSEL fabrication may differ from the foregoing description in some implementations.

As described above, the metastructure 31 can be formed, for example, prior to formation of the high resistance layer 20. In other implementations, the metastructure 31 can be formed, for example at another stage in the VCSEL fabrication process. For example, in some implementations, the metastructure 31 is formed after the dry etch of FIG. 5, but before formation of the insulation film 18 in FIG. 6. In any event, the metastructure 31 can be formed in the one or more outer semiconductor layers of the upper reflector layer 16. The following paragraphs describe various implementations for forming the metastructure 31.

In accordance with processes described in greater detail below, features that correspond to a layout or pattern of meta-atoms are formed in a resist layer. Some of the processes use nano-imprint lithography (NIL) to form the features in the resist layer, whereas other processes use deep ultraviolet (DUV) lithography to form the features in the resist layer. In some instances, the lateral resolution of features formed by NIL may be superior to features formed by DUV because tools (e.g., molds) used in NIL can be manufactured using e-beam lithography which has relatively higher lateral resolution. Consequently, in some cases, it may be desirable to use the NIL processes for fabricating optical elements having high resolution nano-sized features.

As explained below, some of the processes use hardmasks, which can facilitate etching deep structures because they are highly resistant to etchants. The hardmasks can be, for example, a metal that has good adhesion properties to the high-refractive index layer and that exhibits good etch resistance (i.e., high selectivity). Examples of the hardmask material include chrome, titanium, or aluminum. Silicon nitride or silicon dioxide are other hardmask materials that may be used in some instances.

Using hardmasks in combination with NIL processes can facilitate manufacturing high-aspect ratio meta-atoms because the lateral dimensions are defined by imprinting (which, in turn, is defined by e-beam lithography), and the trench depths are defined by the ability of the hardmasks to resist etching. High-aspect ratio meta-atoms may be desirable in some cases.

FIGS. 9A through 9I illustrate various steps in a first example process for forming the metastructure 31. In FIG. 9A, 112 represents the one or more outer semiconductor layers of the upper reflector layer 16 in which the metastructure is to be formed, and 110 represents the underlying layers (e.g., the remaining semiconductor layers of the upper reflector layer 16, the active region 14, the lower reflector layer 12, and the substrate 10). As shown in FIG. 9B, a resist layer 114 is deposited onto the layer 112, for example by spin coating or jetting. If the resist layer 114 is deposited by spin coating, the spin speed can be, for example, in the range of 2000 to 7000 rotations per minute (rpm), depending on the particular resist used and the degree to which the resist is diluted in organic solvent. In some instances, the resist layer 114 is deposited to a final thickness in the range of 50-500 nm. The resist layer 114 can be, for example, a thermal resist (e.g., a thermoplast, such as a plastic polymer, which becomes softer when heated and harder when cooled). After depositing the resist layer 114, it may be heated to drive off excess organic solvent.

Next, the resist layer 114 is heated above it glass transition temperature (Tg) (e.g., 80° C. to 200° C.), and, as shown in FIG. 9C, a tool (e.g. a mold) 116 is pressed into the resist layer. The surface of the tool 116 facing the resist layer 114 includes small nano-features 118 that are imprinted into the resist layer. The resist layer 114 then is allowed to cool below its Tg, and the tool 116 subsequently is released from the resist layer.

As shown in FIG. 9D, after releasing the tool 116 from the resist layer 114, an imprinted resist layer 114A remains on the layer 112. A residual layer 120 having a thickness, for example, of 5 nm to 50 nm also may remain on the surface of the layer 112. Exposed portions of the residual layer 120 are removed, for example, with directional oxygen plasma using a high-vacuum tool or using a barrel asher. Preferably, the portions of the residual layer 120 are removed at a highly controlled rate (e.g., removed at a rate of 0.1 to 5 nm per second). The resulting structure 122, shown in FIG. 9E, includes the imprinted resist layer 114A.

As shown in FIG. 9F, a hardmask material 124 then is deposited on the exposed upper surfaces of the resist layer 114A and the layer 112. In the illustrated example, a high-vacuum tool can be used to deposit the hardmask material 124 (e.g., deposition can be by e-beam deposition or by thermal deposition with a high-vacuum). The high vacuum enables directional deposition of the hardmask material which is needed so that the sidewalls 126 of the resist layer 114A preferably are not covered in hardmask material.

Next, the resist 114A, along with the portions of the hardmask material 124 that are on the resist, is lifted off. This lift-off process can be performed, for example, in a beaker using a solution such as an organic solvent (e.g., acetone). Sonic/ultrasound can be applied to facilitate the liftoff process. As indicated by FIG. 9G, the portions 124A of the hardmask material that were deposited on the surface of the layer 112 remain even after the lift-off process.

As shown in FIG. 9H, the layer 112 then is etched, for example, using inductively coupled plasma (ICP). The hardmask 124A serves as a mask so that the layer 112 is etched selectively. A high-bias (i.e., highly directional) plasma should be used to obtain trenches 126 having substantially vertical sidewalls in the etched layer 112.

Next, the hardmask 124A is removed, for example, by a high-power oxygen and nitrogen plasma in a barrel asher. FIG. 9I shows an example of the resulting structure 128, including the meta-atoms 130 of the metastructure formed in the layer 112.

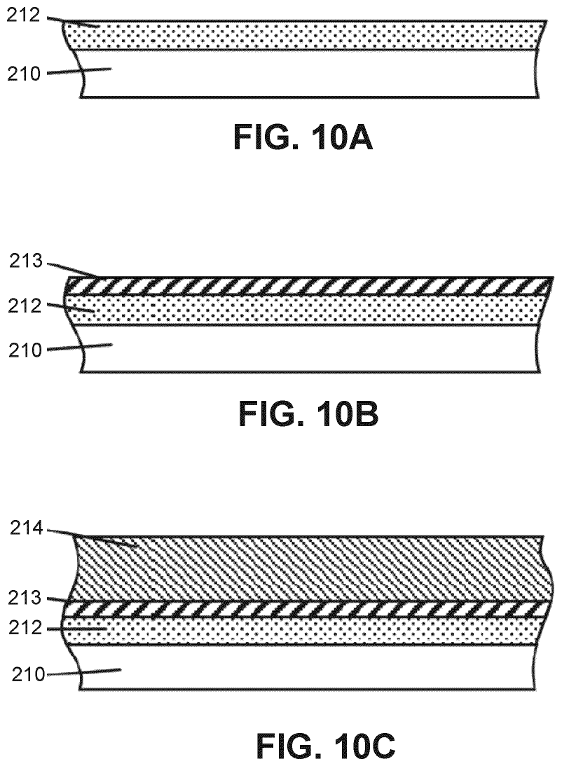

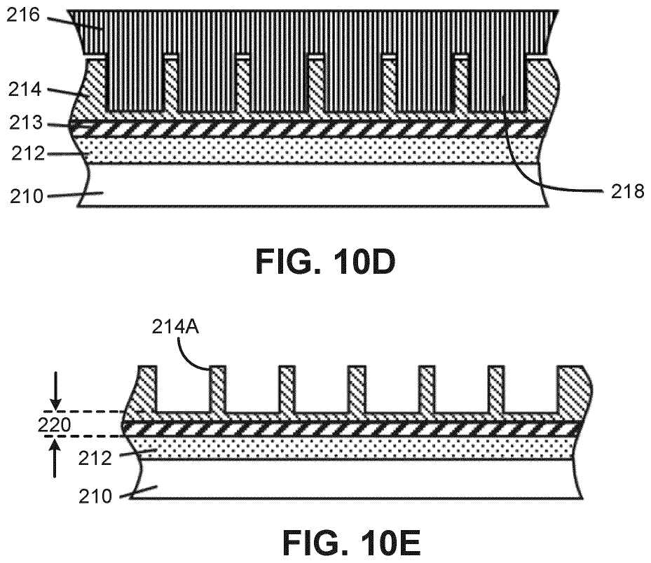

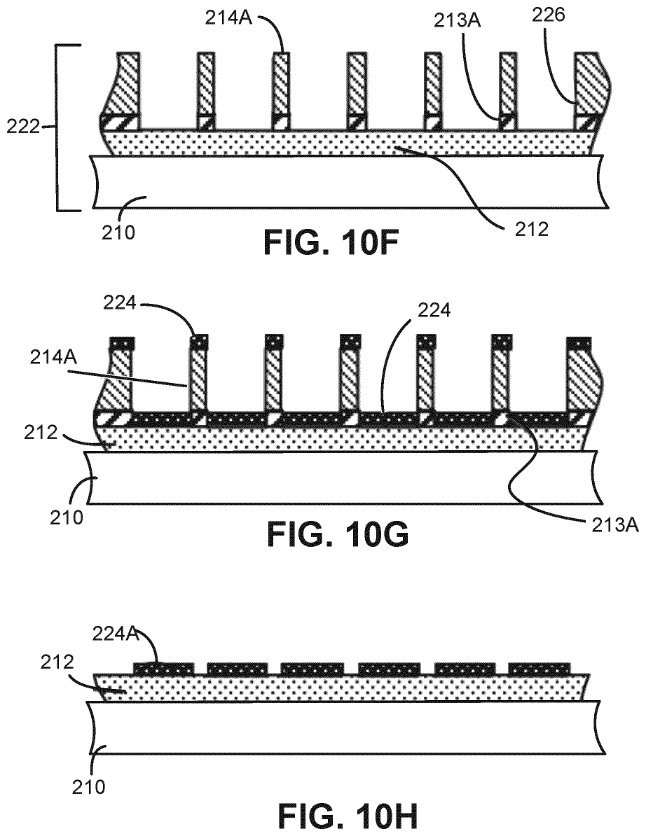

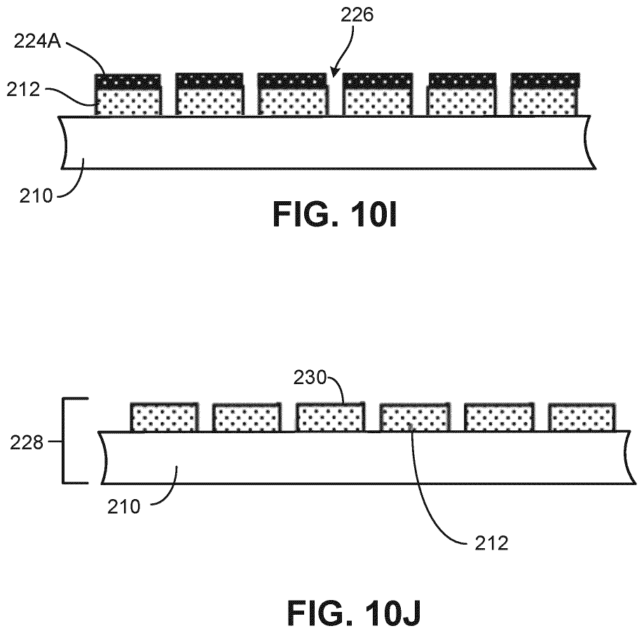

FIGS. 10A through 10J illustrate various steps in a second example process for forming the metastructure 31. In FIG. 10A, 212 represents the one or more outer semiconductor layers of the upper reflector layer 16 in which the metastructure is to be formed, and 210 represents the underlying layers (e.g., the remaining semiconductor layers of the upper reflector layer 16, the active region 14, the lower reflector layer 12, and the substrate 10). As shown in FIGS. 10B and 10C, respectively, a thin liftoff resist layer 213 is deposited on the layer 212, and a resist layer 214 is deposited on the liftoff layer 213. The resist layer 214 can be, for example, a UV resist that hardens when exposed to ultraviolet (UV) radiation. Using a UV resist for the imprinting can be advantageous in some cases. Typically, there may be a thermal expansion mismatch between the imprinting tool (216 in FIG. 10D) and the substrate 210. If the imprinting were to involve heating, the tool 216 may distort, which could then distort the resulting metastructures. On the other hand, a UV imprint does not require such heating, and thus distortion as a result of heating would not occur.

The liftoff resist 213 can be composed, for example, of a polymeric material that has better dissolution properties than the UV resist 214. The liftoff resist 213 can be dissolved, for example, in an organic solvent such as acetone. As the UV resist 214 may undergo significant crosslinking upon UV exposure, it may be difficult to dissolve it in typical solvents. The liftoff resist layer 213 can be deposited, for example by spin coating. In that case, the spin speed can be, for example, in the range of 2000 to 7000 rotations per minute (rpm), depending on the particular resist used and the degree to which the resist is diluted in organic solvent. The resist layer 213 can be heated to drive off excess organic solvent. In some instances, the resist layer 213 is deposited to a final thickness in the range of 50-200 nm.

In some implementations, the liftoff resist layer 213 can be omitted. However, because the UV resist layer 214 may have relatively high chemical resistance after exposure to UV radiation, it can be advantageous to provide a separate liftoff resist layer 213 to facilitate subsequent processing steps, including removal of the UV resist layer 214.

The UV resist layer 214 can be deposited, for example by spin coating. In that case, the spin speed can be, for example, in the range of 2000 to 7000 rotations per minute (rpm), depending on the particular resist used and the degree to which the resist is diluted in organic solvent. The resist layer 214 can be heated to drive off excess organic solvent. In some instances, the resist layer 214 is deposited to a final thickness in the range of 50-500 nm.

Next, as shown in FIG. 10D, a tool (e.g. a mold) 216 is pressed into the resist layer. The surface of the tool 216 facing the resist layer 214 includes small nano-features 218 that are imprinted into the resist layer. The resist layer 214 then is exposed to UV radiation, and the tool 216 is released from the resist layer.

As shown in FIG. 10E, after the tool 216 is released, a thin residual resist layer 220 remains. In some instances, the thickness of the residual layer 220 consists, for example, of 5 nm to 50 nm of the resist layer 214 plus the thickness of the liftoff resist layer 213. Exposed portions of the residual layer 220, including the liftoff resist layer and UV resist layer are removed, for example, with directional oxygen plasma using a high-vacuum tool or using a barrel asher. The residual layer 220 should be removed at a highly controlled rate (e.g., removed at a rate of 0.1 to 5 nm per second). The resulting structure 222, shown in FIG. 10F, includes the imprinted resist layer 214A and the underlying portions 213A of the liftoff layer.

As shown in FIG. 10G, a hardmask material 224 then is deposited on the exposed upper surfaces of the resist layer 214A and the layer 212. In the illustrated example, a high-vacuum tool can be used to deposit the hardmask material 224 (e.g., deposition can be by e-beam deposition or by thermal deposition with a high-vacuum). The high vacuum enables directional deposition of the hardmask material which is needed so that the sidewalls 226 of the resist layer 214A preferably are not covered in hardmask material.

Next, the resist layer 214A and 213A, along with the portions of the hardmask material 224 that are on the resist layer, is lifted off. This lift-off process can be performed, for example, in a beaker using a solution such as an organic solvent such as acetone. Sonic/ultrasound can be applied to facilitate the liftoff process. As indicated by FIG. 10H, the portions 224A of the hardmask material that were deposited on the surface of the layer 212 remain even after the lift-off process.

As shown in FIG. 10I, the layer 212 then is etched, for example, using inductively coupled plasma (ICP). The hardmask 224A serves as a mask so that the layer 212 is etched selectively. A high-bias (i.e., highly directional) plasma should be used to obtain trenches 226 having substantially vertical sidewalls in the etched layer 212.

Next, the hardmask 224A is removed, for example, by a high-power oxygen and nitrogen plasma in a barrel asher. FIG. 10J shows an example of the resulting structure 228, including the meta-atoms 230 of the metastructure formed in the layer 212.

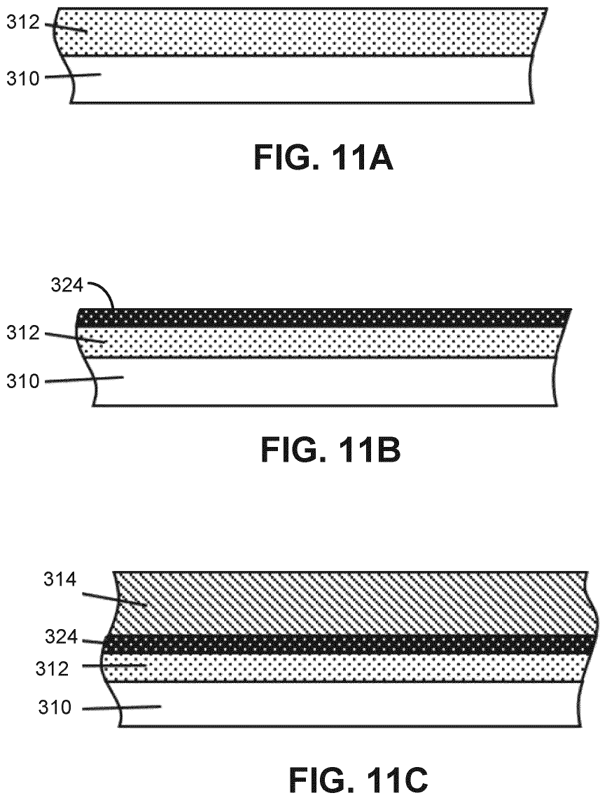

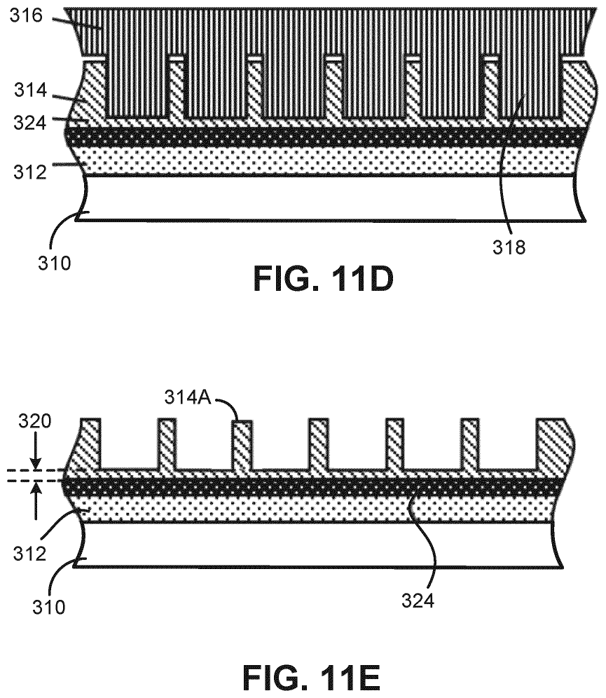

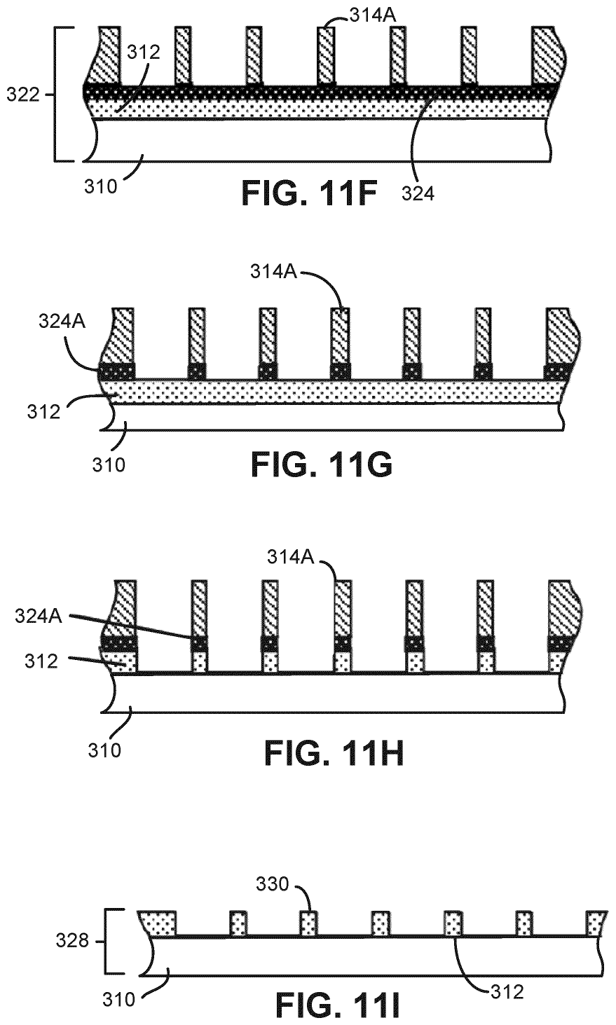

FIGS. 11A through 11I illustrate various steps in a third example process for forming the metastructure 31. In FIG. 11A, 312 represents the one or more outer semiconductor layers of the upper reflector layer 16 in which the metastructure is to be formed, and 310 represents the underlying layers (e.g., the remaining semiconductor layers of the upper reflector layer 16, the active region 14, the lower reflector layer 12, and the substrate 10). As shown in FIG. 3B, a hardmask layer 324 is deposited onto the layer 312. In this case, a high-vacuum tool is not needed for the hardmask deposition. In particular (in contrast to the first and second processes described above in connection with FIGS. 9A-9I and 10A-10J), there is no need at this stage to avoid covering side walls with the hardmask material. Thus, directional deposition of the hardmask material is not needed in this process of FIGS. 11A-11I. Consequently, the process can be carried out, for example, using sputtering.

Next, as shown in FIG. 11C, a resist layer 314 is deposited onto the hardmask layer 324, for example, by either spin coating or jetting. If the resist layer 314 is deposited by spin coating, the spin speed can be, for example, in the range of 2000 to 7000 rotations per minute (rpm), depending on the particular resist used and the degree to which the resist is diluted in organic solvent. The resist layer 314 can be heated to drive off excess organic solvent. In some instances, the resist layer 314 is deposited to a final thickness in the range of 50-500 nm. The resist layer can be, for example, a thermal resist (as described in the first process) or a UV resist (as described in the second process).

Next, as shown in FIG. 11D, a tool (e.g. a mold) 316 is pressed into the resist layer 314. The surface of the tool 316 facing the resist layer 314 includes small nano-features 318 that are imprinted into the resist layer. The resist 314 then can be hardened. For example, if a thermal resist is used, the resist layer 314 can be heated above it glass transition temperature before, and then allowed to cool before the tool 316 is released from the resist layer. If a UV resist is used, then the resist layer 314 can be exposed to UV radiation before the tool 316 is released from the resist layer.

As shown in FIG. 11E, after the tool 316 is released, a thin residual resist layer 320 remains. In some instances, the thickness of the residual layer 320 is in the range of 5 nm to 50 nm. Exposed portions of the residual layer 320 are removed, for example, with directional oxygen plasma using a high-vacuum tool or using a barrel asher. The residual layer 320 should be removed at a highly controlled rate (e.g., removed at a rate of 0.1 to 5 nm per second). The resulting structure 322, shown in FIG. 11F, includes the imprinted resist layer 314A, as well as the hardmask layer 324.

Next, the hardmask layer 324 is etched, for example, using chlorine and oxygen plasma. The resist layer 314A serves as a mask so that the hardmask layer 324 is etched selectively. Etching the hardmask layer results in a hardmask 324A, as shown in FIG. 11G. In contrast to the liftoff process described in connection with FIGS. 10A-10J, etching the hardmask can, in some cases, be advantageous because it leaves fewer artifacts such as particles and other contaminants.

Then, as shown in FIG. 11H, the layer 312 is etched, for example, using inductively coupled plasma (ICP). The resist layer 314A and the hardmask 324A serve as a mask so that the layer 312 is etched selectively. A high-bias (i.e., highly directional) plasma should be used to obtain trenches 326 having substantially vertical sidewalls in the etched layer 312.

Next, the hardmask 324A and resist 314A that remain on the layer 312 are removed, for example, by a high-power oxygen and nitrogen plasma in a barrel asher. FIG. 11I shows an example of the resulting structure 328, including the meta-atoms 330 of the metastructure formed in the layer 312.

The foregoing process illustrated by FIGS. 11A-11I can provide various advantages in some implementations. For example, only one layer of resist is needed even when a UV resist is used. Further, the hardmask 324A is defined by etching and not a liftoff process (see FIG. 11G). Etching the hardmask can result in higher quality edge definition for the meta-atoms. Further, the process steps after the imprinting (i.e., after FIG. 11D) can be done in the same processing chamber, which can help facilitate mass production. Also, the residual layer removal step permits precise removal of resist material (see FIG. 11F). Consequently, meta-atom lateral dimensions that are smaller than what can be achieved with some e-beam and NIL processes are possible.

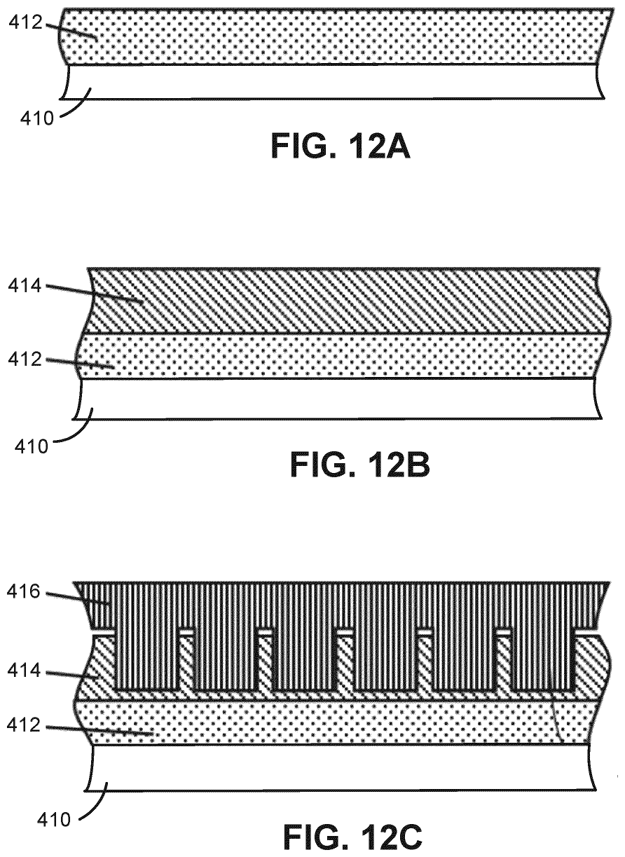

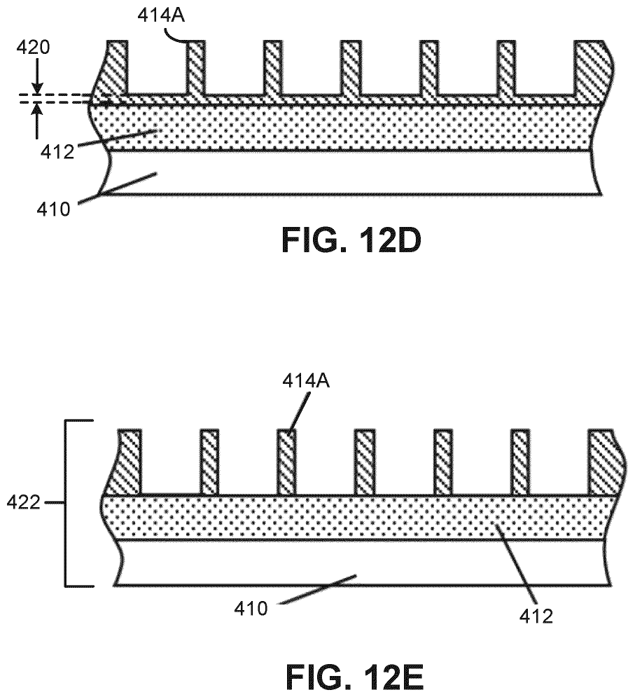

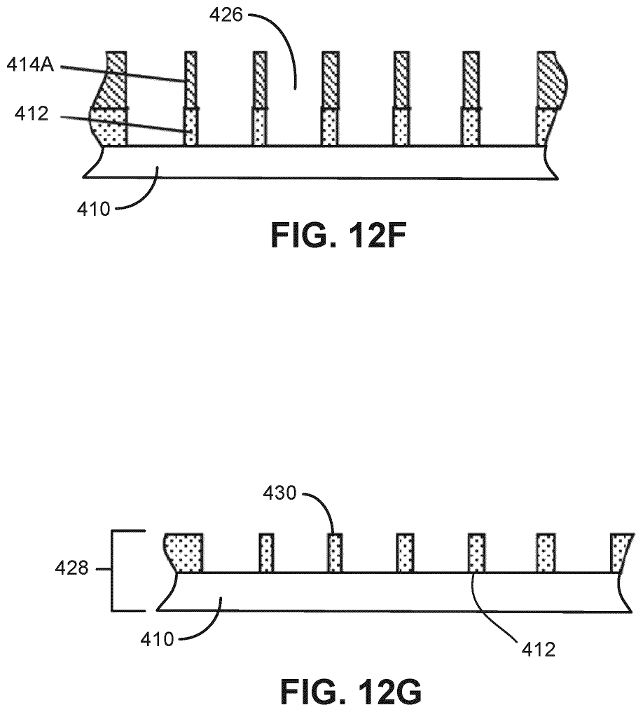

FIGS. 12A through 12G illustrate various steps in a fourth example process for forming the metastructure 31. The process steps associated with FIGS. 12A-12E can be the substantially the same as the process steps described in connection with FIGS. 9A-9E. However, the process of FIGS. 12A-12I does not require use of a hardmask and does not require use of liftoff.

In FIG. 12A, 412 represents the one or more outer semiconductor layers of the upper reflector layer 16 in which the metastructure is to be formed, and 410 represents the underlying layers (e.g., the remaining semiconductor layers of the upper reflector layer 16, the active region 14, the lower reflector layer 12, and the substrate 10). As shown in FIG. 12B, a resist layer 414 is deposited onto the layer 412, for example by spin coating or jetting. If the resist layer 414 is deposited by spin coating, the spin speed can be, for example, in the range of 2000 to 7000 rotations per minute (rpm), depending on the particular resist used and the degree to which the resist is diluted in organic solvent. In some instances, the resist layer 414 is deposited to a final thickness in the range of 50-500 nm. The resist layer can be, for example, a thermal resist (as described in the first process) or a UV resist (as described in the second process).

Next, as shown in FIG. 12C, a tool (e.g. a mold) 416 is pressed into the resist layer 414. The surface of the tool 416 facing the resist layer 414 includes small nano-features 418 that are imprinted into the resist layer. If a thermal resist is used, the resist layer 414 can be heated above it glass transition temperature before, and then allowed to cool before the tool 416 is released from the resist layer. If a UV resist is used, then the resist layer 414 can be exposed to UV radiation before the tool 416 is released from the resist layer.

As shown in FIG. 12D, after releasing the tool 416 from the resist layer 414, an imprinted resist layer 414A remains on the layer 412. A residual layer 420 having a thickness, for example, of 5 nm to 50 nm also may remain on the surface of the layer 412. Exposed portions of the residual layer 420 are removed, for example, with directional oxygen plasma using a high-vacuum tool or using a barrel asher. Preferably, the portions of the residual layer 420 are removed at a highly controlled rate (e.g., removed at a rate of 0.1 to 5 nm per second). The resulting structure 422, shown in FIG. 12E, includes the imprinted resist layer 414A.

As shown in FIG. 12F, the layer 412 is etched, for example, using inductively coupled plasma (ICP). The resist layer 414A serves as a mask so that the layer 412 is etched selectively. A high-bias (i.e., highly directional) plasma should be used to obtain trenches 426 having substantially vertical sidewalls in the etched layer 412.

The portions 414A of the resist layer can be removed, for example, by a high-power oxygen and nitrogen plasma in a barrel asher. FIG. 12G shows an example of the resulting structure 428, including the meta-atoms 430 of the metastructure formed in the layer 412.

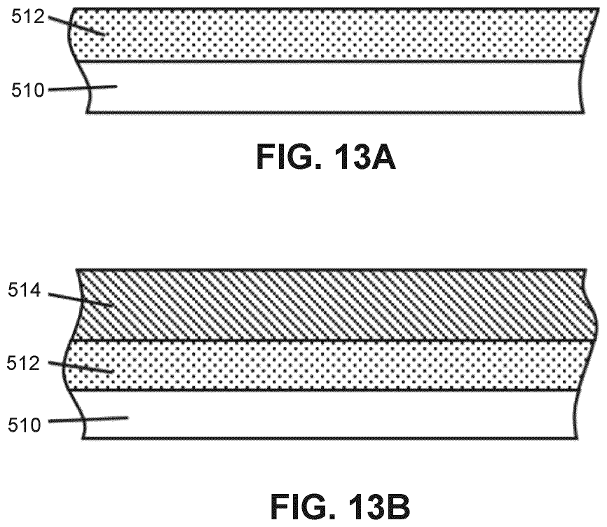

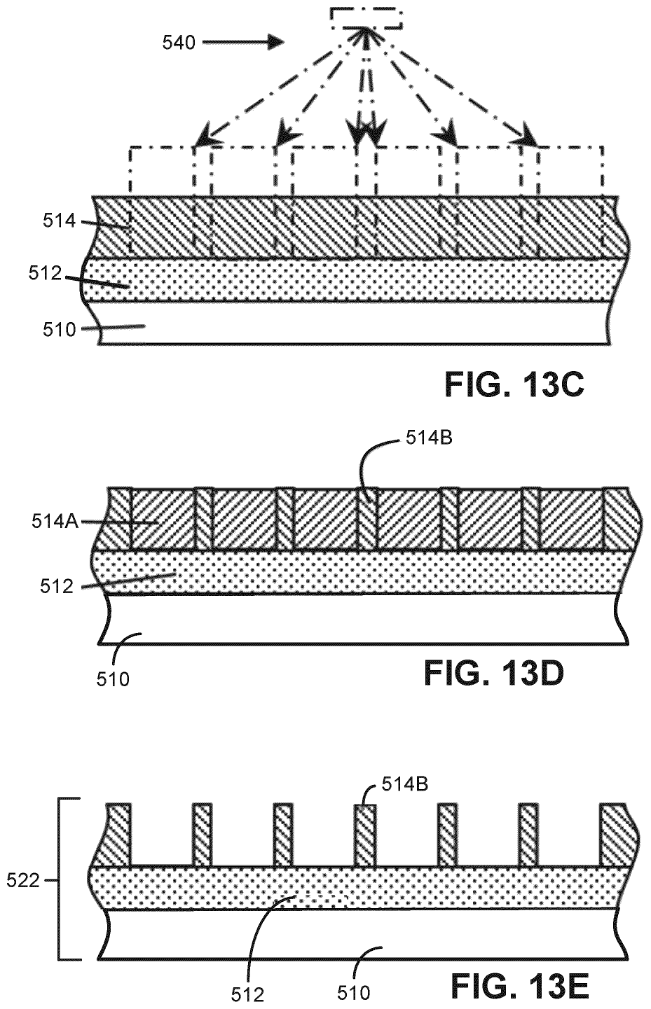

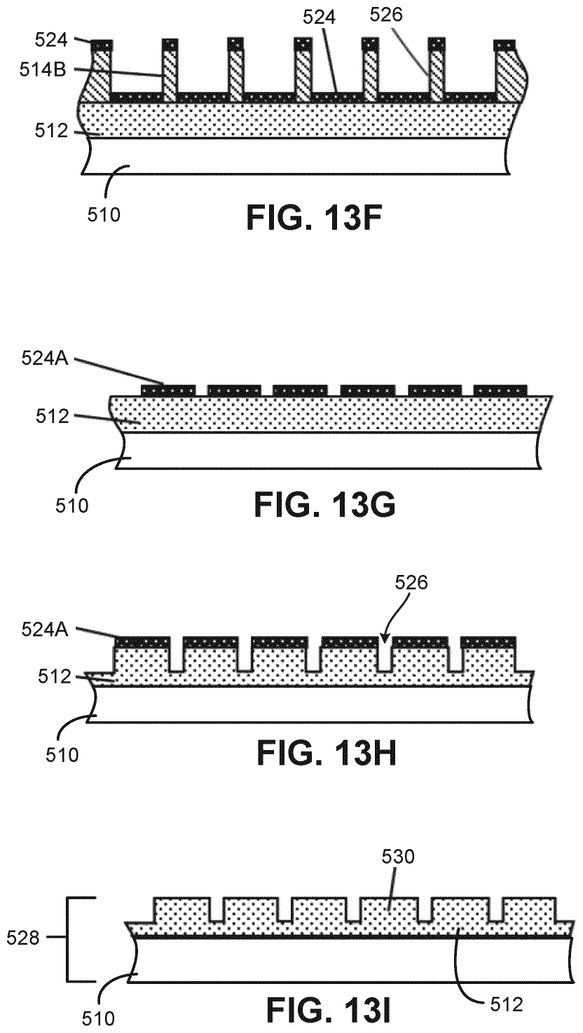

FIGS. 13A through 13I illustrate various steps in a fifth example process for forming the metastructure 31. In contrast to the first through the fourth examples above, this fifth process uses deep ultraviolet (DUV) lithography instead of nano-imprint lithography (NIL) to form the features in a resist layer.

In FIG. 13A, 512 represents the one or more outer semiconductor layers of the upper reflector layer 16 in which the metastructure is to be formed, and 510 represents the underlying layers (e.g., the remaining semiconductor layers of the upper reflector layer 16, the active region 14, the lower reflector layer 12, and the substrate 10). As shown in FIG. 13B, a UV resist layer 514 is deposited onto the layer 512, for example, by spin coating. The spin speed can be, for example, in the range of 2000 to 7000 rotations per minute (rpm), depending on the particular resist used and the degree to which the resist is diluted in organic solvent. In some instances, the resist layer 514 is deposited to a final thickness in the range of 50-500 nm. The UV resist layer 514 can be a resist that hardens when exposed to ultraviolet (UV) radiation.

Next, as shown in FIG. 13C, portions of the resist layer 514 are exposed to UV radiation using a DUV tool 540. FIG. 13D indicates portions 514A of the resist 514 that are exposed to the UV radiation, and portions 514B that are unexposed. In this example process, there is no residual resist layer as occurs in some of the previous examples described above. The resist layer 514 then is developed using, for example, a suitable solvent, such that the exposed portions 514A are removed. The resulting structure 522, shown in FIG. 13E, includes a pattern of resist (e.g., the unexposed portions 514B of the resist layer 514). Depending on the type of resist, in some instances, unexposed portions of the resist are removed instead of the exposed portions. In such cases, the DUV tool 540 should be configured to expose regions of the resist layer that remain after the resist is developed.

The process steps associated with FIGS. 13F-13H can be substantially the same as the process steps described in connection with FIGS. 9F-9H. As shown in FIG. 13F, a hardmask material 524 is deposited on the exposed upper surfaces of the layer 512 and on the resist layer material 514B. In the illustrated example, a high-vacuum tool can be used to deposit the hardmask material 524 (e.g., deposition can be by e-beam deposition or by thermal deposition with a high-vacuum). The high vacuum enables directional deposition of the hardmask material which is needed so that the sidewalls 526 of the resist layer material 514B preferably are not covered in hardmask material.

Next, the resist layer material 514B, along with the portions of the hardmask material 524 that are on the resist layer material, are lifted off. This lift-off process can be performed, for example, in a beaker using a solution such as an organic solvent (e.g., acetone). Sonic/ultrasound can be applied to facilitate the liftoff process. As indicated by FIG. 13G, the portions 524A of the hardmask material that were deposited on the surface of the layer 512 remain even after the lift-off process.

As shown in FIG. 13H, the layer 512 then is etched, for example, using inductively coupled plasma (ICP). The hardmask 524A serves as a mask so that the layer 312 is etched selectively. A high-bias (i.e., highly directional) plasma should be used to obtain trenches 526 having substantially vertical sidewalls in the etched layer 512.

Next, the hardmask 524A is removed, for example, by a high-power oxygen and nitrogen plasma in a barrel asher. FIG. 13I shows an example of the resulting structure 528, including the meta-atoms 530 of the metastructure formed in the layer 512.

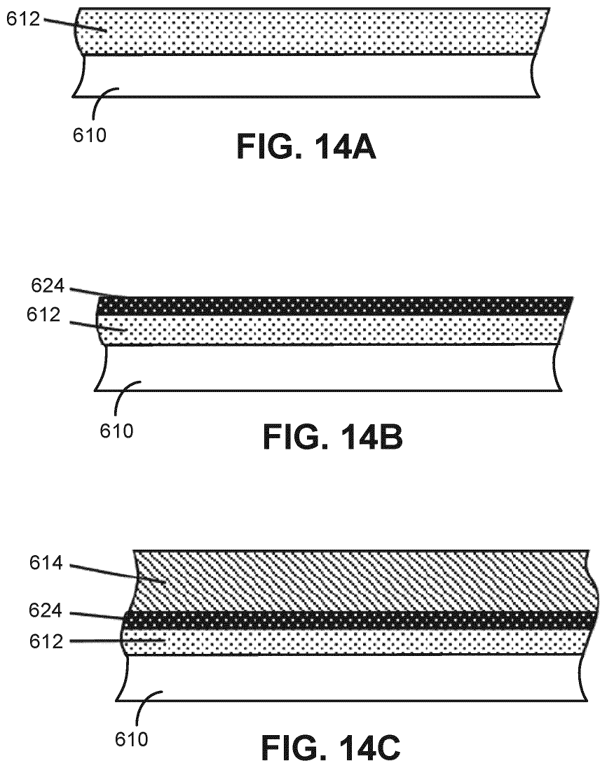

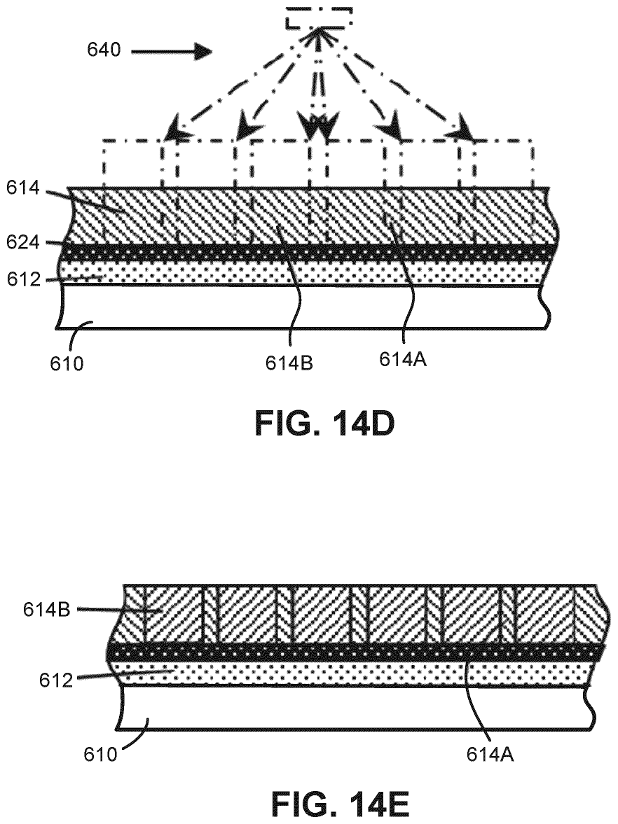

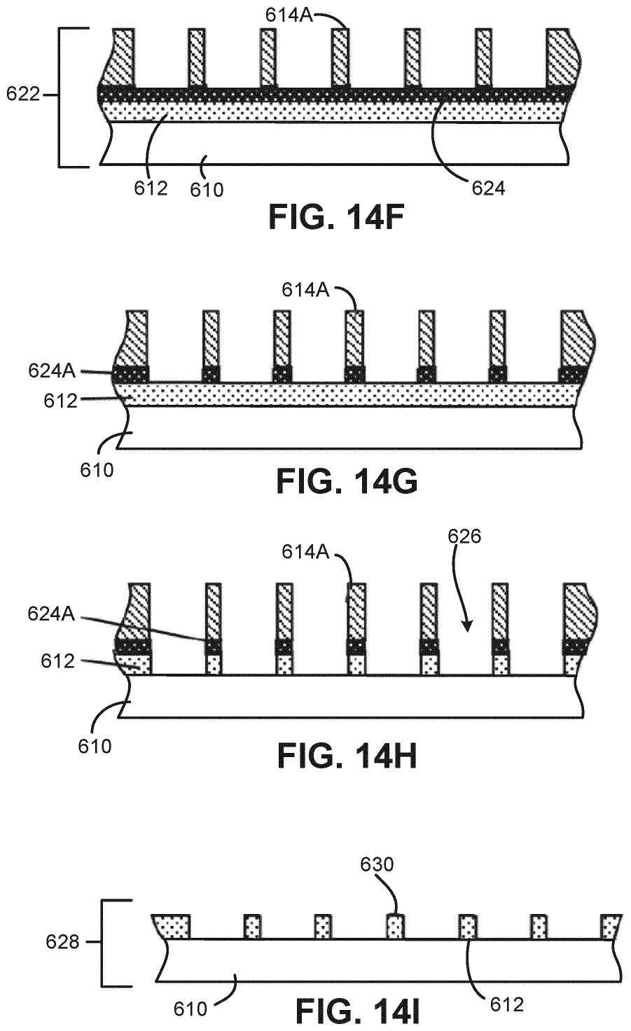

FIGS. 14A through 14I illustrate various steps in a sixth example process for forming the metastrcuture 31. This sixth process uses deep ultraviolet (DUV) lithography to form features in a UV resist layer. The process steps associated with FIGS. 14A-14C can be substantially the same as the process steps associated with FIGS. 11A-11C. Likewise, the process steps associated with FIGS. 14G-14H can be substantially the same as the process steps associated with FIGS. 11G-11H.

In FIG. 14A, 612 represents the one or more outer semiconductor layers of the upper reflector layer 16 in which the metastructure is to be formed, and 610 represents the underlying layers (e.g., the remaining semiconductor layers of the upper reflector layer 16, the active region 14, the lower reflector layer 12, and the substrate 10). As shown in FIG. 14B, a hardmask layer 624 is deposited onto the layer 612. A high-vacuum tool is not needed for the hardmask deposition because directional deposition of the hardmask material is not needed in this process of FIGS. 14A-14I. Consequently, the process can be carried out, for example, using sputtering.

Next, as shown in FIG. 14C, a UV resist layer 614 is deposited onto the hardmask layer 624, for example, by spin coating. The spin speed can be, for example, in the range of 2000 to 7000 rotations per minute (rpm), depending on the particular resist used and the degree to which the resist is diluted in organic solvent. The resist layer 614 can be heated to drive off excess organic solvent. In some instances, the resist layer 614 is deposited to a final thickness in the range of 50-500 nm.

Next, as shown in FIG. 14D, portions of the resist layer 614 are exposed to UV radiation using a DUV tool 640. FIG. 14E indicates portions 614A of the resist 614 that are exposed to the UV radiation, and portions 614B that are unexposed. In this example process, there is no residual resist layer as occurs in some of the previous examples described above. The resist layer 614 then is developed using, for example, a suitable solvent, such that the exposed portions 614A are removed. The resulting structure 622, shown in FIG. 14F, includes a pattern of resist (e.g., the unexposed portions 614B of the resist layer 614). Depending on the type of resist, in some instances, unexposed portions of the resist are removed instead of the exposed portions. In such cases, the DUV tool 640 should be configured to expose regions of the resist layer that remain after the resist is developed. The UV resist layer 614 can be a resist that hardens when exposed to ultraviolet (UV) radiation.

Next, the hardmask layer 624 is etched, for example, using chlorine and oxygen plasma. The resist layer 614B serves as a mask so that the layer 612 is etched selectively. Etching the hardmask layer results in a hardmask 624A, as shown in FIG. 14G. Etching the hardmask (instead, for example, of using a liftoff process) can, in some cases, be advantageous because it leaves fewer artifacts such as particles and other contaminants.

Then, as shown in FIG. 14H, the layer 612 is etched, for example, using inductively coupled plasma (ICP). The resist layer 614B and the hardmask 624A serve as a mask so that the layer 612 is etched selectively. A high-bias (i.e., highly directional) plasma should be used to obtain trenches 626 having substantially vertical sidewalls in the etched layer 612.

Next, the hardmask material 624A and the resist layer material 614B that remain on the layer 612 are removed, for example, by a high-power oxygen and nitrogen plasma in a barrel asher. FIG. 14I shows an example of the resulting structure 628, including the meta-atoms 630 of the metastructure formed in the layer 612.

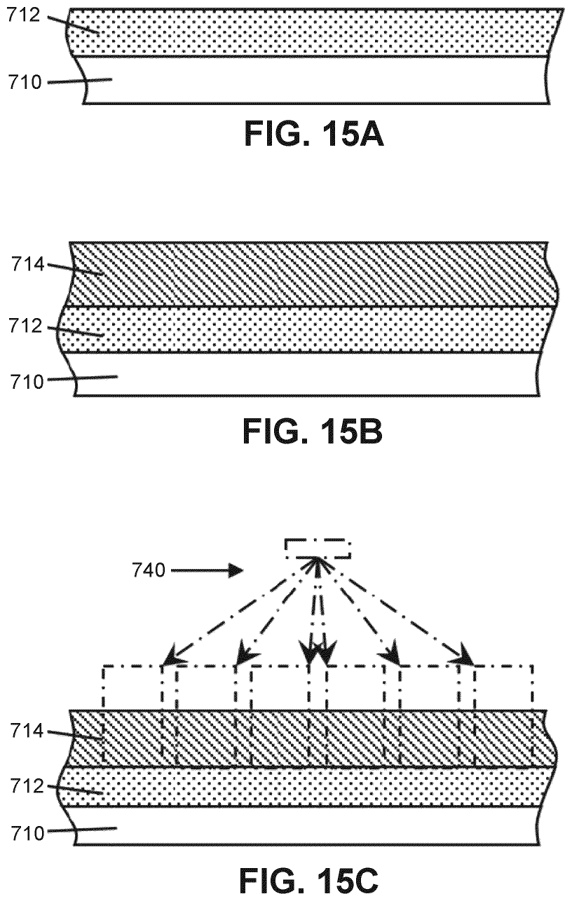

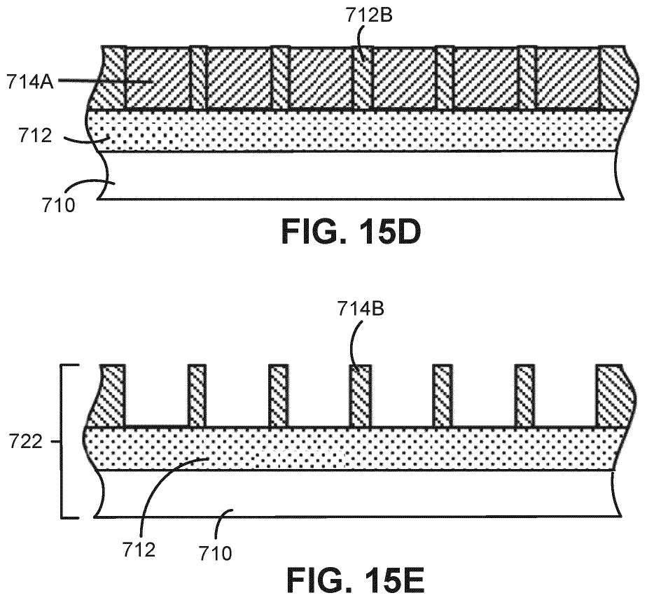

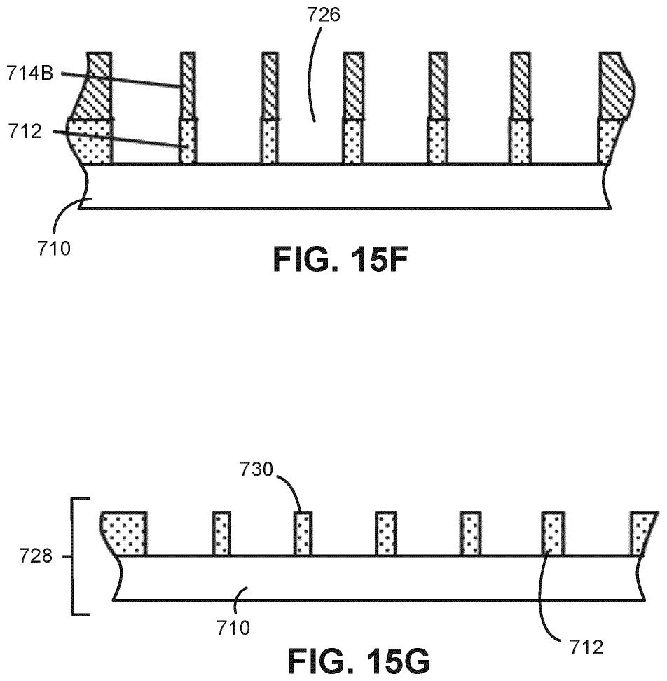

FIGS. 15A through 15G illustrate various steps in a seventh example process for forming the metastructure 31. This seventh process uses deep ultraviolet (DUV) lithography to form features in a UV resist layer. The process steps associated with FIGS. 15A-15D can be substantially the same as the process steps associated with FIG. 13A-13D. Likewise, the process steps associated with FIG. 15F can be substantially the same as the process steps associated with FIG. 12F.

In FIG. 15A, 712 represents the one or more outer semiconductor layers of the upper reflector layer 16 in which the metastructure is to be formed, and 710 represents the underlying layers (e.g., the remaining semiconductor layers of the upper reflector layer 16, the active region 14, the lower reflector layer 12, and the substrate 10). As shown in FIG. 15B, a UV resist layer 714 is deposited onto the layer 712, for example, by spin coating. The spin speed can be, for example, in the range of 2000 to 7000 rotations per minute (rpm), depending on the particular resist used and the degree to which the resist is diluted in organic solvent. In some instances, the resist layer 714 is deposited to a final thickness in the range of 50-500 nm.

Next, as shown in FIG. 15C, portions of the resist layer 714 are exposed to UV radiation using a DUV tool 740. FIG. 15D indicates portions 714A of the resist 714 that are exposed to the UV radiation, and portions 714B that are unexposed. In this example process, there is no residual resist layer as occurs in some of the previous examples described above. The resist layer 714 then is developed using, for example, a suitable solvent, such that the exposed portions 714A are removed. The resulting structure 722, shown in FIG. 7E, includes a pattern of resist (e.g., the unexposed portions 714B of the resist layer 714). Depending on the type of resist, in some instances, unexposed portions of the resist are removed instead of the exposed portions. In such cases, the DUV tool 740 should be configured to expose regions of the resist layer that remain after the resist is developed. The UV resist layer 714 can be a resist that hardens when exposed to ultraviolet (UV) radiation.

As shown in FIG. 15F, the layer 712 is etched, for example, using inductively coupled plasma (ICP). The resist layer material 714B serves as a mask so that the layer 712 is etched selectively. A high-bias (i.e., highly directional) plasma should be used to obtain trenches 726 having substantially vertical sidewalls in the etched layer 412.

The portions 714B of the resist layer can be removed, for example, by a high-power oxygen and nitrogen plasma in a barrel asher. FIG. 15G shows an example of the resulting structure 728, including the meta-atoms 730 of the metastructure formed in the layer 712.

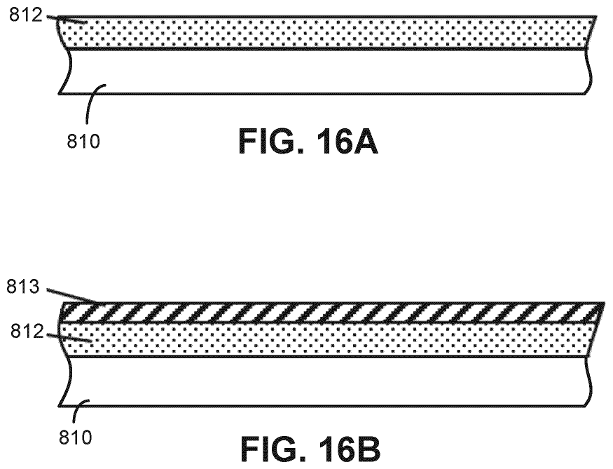

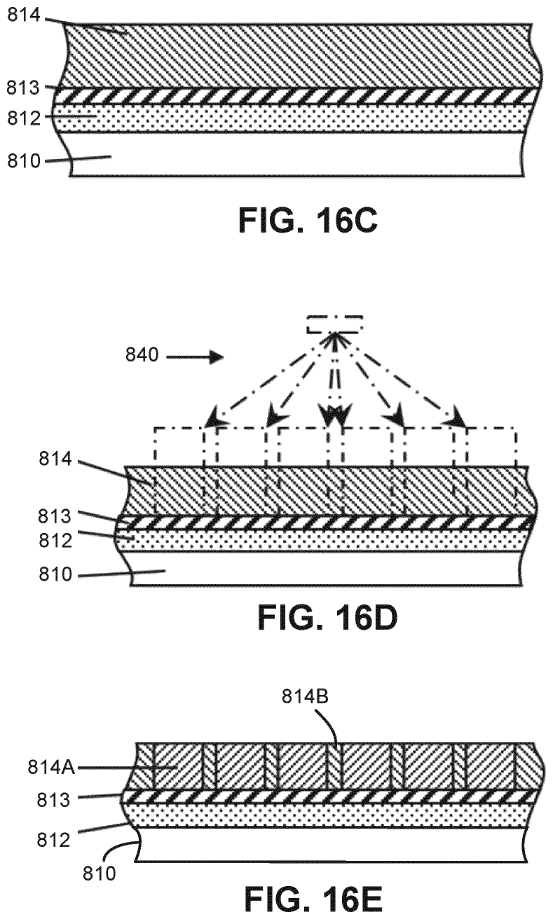

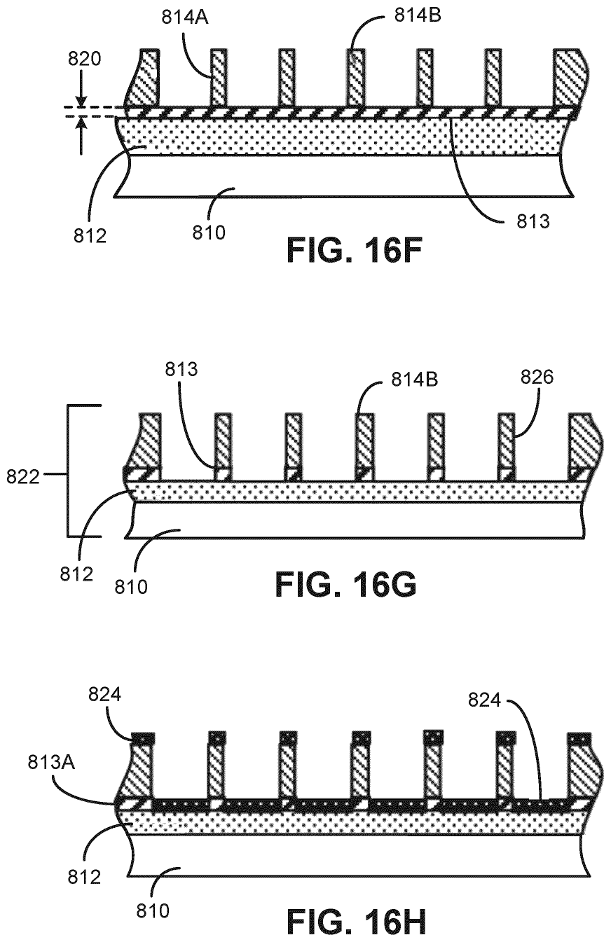

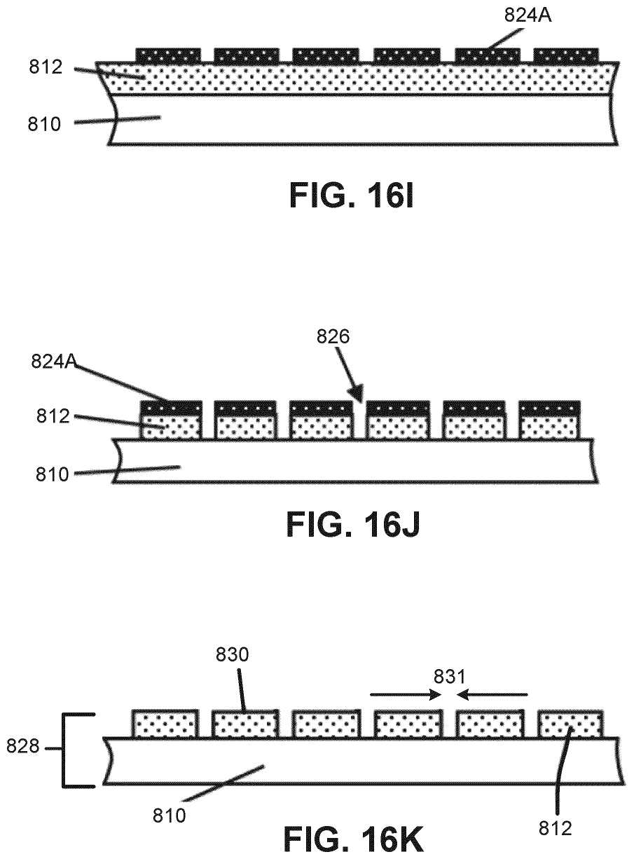

FIGS. 16A through 16K illustrate various steps in an eighth example process for forming the metastructure 31. This eighth process uses deep ultraviolet (DUV) lithography to form features in a UV resist layer. The process steps associated with FIGS. 16A-16C can be substantially the same as the process steps associated with FIG. 10A-10C. Likewise, the process steps associated with FIGS. 816-16J can be substantially the same as the process steps associated with FIGS. 10G-10I.

In FIG. 16A, 812 represents the one or more outer semiconductor layers of the upper reflector layer 16 in which the metastructure is to be formed, and 810 represents the underlying layers (e.g., the remaining semiconductor layers of the upper reflector layer 16, the active region 14, the lower reflector layer 12, and the substrate 10). As shown in FIGS. 16B and 16C, respectively, a thin liftoff resist layer 813 is deposited on the layer 812, and a UV resist layer 814 is deposited on the liftoff layer 813. The layer 814 can be deposited, for example by spin coating. The spin speed can be, for example, in the range of 2000 to 7000 rotations per minute (rpm), depending on the particular resist used and the degree to which the resist is diluted in organic solvent. The resist layer 814 can be heated to drive off excess organic solvent. In some instances, the resist layer 814 is deposited to a final thickness in the range of 50-500 nm. The UV resist layer 814 can be a resist that hardens when exposed to ultraviolet (UV) radiation.

In some implementations, the liftoff resist layer 813 can be omitted. However, because the UV resist layer 814 may have relatively high chemical resistance after exposure to UV radiation, it can be advantageous to provide a separate liftoff resist layer 813 to facilitate subsequent processing steps, including removal of the resist layer 814.

Next, as shown in FIG. 16D, portions of the resist layer 814 are exposed to UV radiation using a DUV tool 840. FIG. 16E indicates portions 814A of the resist 814 that are exposed to the UV radiation, and portions 814B that are unexposed. The resist layer 814 then is developed using, for example, a suitable solvent, such that the exposed portions 814A are removed. As shown in FIG. 16E, a residual layer 820 composed of the liftoff resist layer 813 also remains on the surface of the layer 812.

Exposed portions of the residual layer 820 (i.e., exposed portions of the liftoff resist layer 813) are removed, for example, with directional oxygen plasma using a high-vacuum tool or using a barrel asher. The residual layer 820 should be removed at a highly controlled rate (e.g., removed at a rate of 0.1 to 5 nm per second). The resulting structure 822, shown in FIG. 16G, includes a pattern of resist, (e.g., the resist layer material 814B and the underlying portions 813A of the liftoff layer).

As shown in FIG. 16H, a hardmask material 824 then is deposited on the exposed upper surfaces of the resist 814B and the layer 812. In the illustrated example, a high-vacuum tool can be used to deposit the hardmask 824 material (e.g., deposition can be by e-beam deposition or by thermal deposition with a high-vacuum). The high vacuum enables directional deposition of the hardmask material which is needed so that the sidewalls 826 of the resist 814B preferably are not covered in hardmask material.

Next, the resist 814B, along with the portions of the hardmask material 824A that are on the resist layer, is lifted off. This lift-off process can be performed, for example, in a beaker using a solution such as an organic solvent such as acetone. Sonic/ultrasound can be applied to facilitate the liftoff process. As indicated by FIG. 16I, the portions 824A of the hardmask material that were deposited on the surface of the layer 812 remain even after the lift-off process.

As shown in FIG. 16J, the layer 812 then is etched, for example, using inductively coupled plasma (ICP). The hardmask 824A serves as a mask so that the layer 812 is etched selectively. A high-bias (i.e., highly directional) plasma should be used to obtain trenches 826 having substantially vertical sidewalls in the etched layer 812.

Next, the hardmask 824A is removed, for example, by a high-power oxygen and nitrogen plasma in a barrel asher. FIG. 16K shows an example of the resulting structure 828, including the meta-atoms 830 of the metastructure formed in the layer 812.

Various modifications will be apparent from the foregoing detailed description. Further, features described above in connection with different implementations may, in some cases, be combined in the same implementation. In some instances, the order of the process steps may differ from that described in the particular examples above. For example, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Accordingly, other implementations also are within the scope of the claims.

1. A method comprising:
providing a sequence of semiconductor layers and processing the sequence of semiconductor layers to form an upper reflector disposed over an active layer, the active layer being disposed over a lower reflector, and the lower reflector layer being disposed over a substrate, wherein the semiconductor layers in which the upper reflector is formed include one or more outer semiconductor layers; and
forming an optical metastructure in the one or more outer semiconductor layers.

2. The method of claim 1 wherein the metastructure is operable to provide a beam shaping function.

3. The method of claim 2 wherein the metastructure is further operable as a partially transmissive optical reflector.

4. The method of claim 1, wherein forming a metastructure in the one or more outer semiconductor layers includes:
providing a hardmask layer on the one or more outer semiconductor layers;
depositing a resist layer on the hardmask layer;
pressing a surface of a tool into the resist layer, wherein the surface of the tool includes features that are imprinted into the resist layer; and
releasing the tool from the resist layer.

5. The method of claim 4 further including:
after releasing the tool form the resist layer, removing portions of a residual resist layer that is on the hardmask layer, so as to expose first portions of the hardmask layer.

6. The method of claim 4 wherein the portions of the residual resist layer are removed using a directional oxygen plasma.

7. The method of claim 4, further including:
selectively etching the hardmask layer to expose first portions of the one or more outer semiconductor layers; and
selectively etching the exposed first portions of the one or more outer semiconductor layers to form trenches therein.

8. The method of claim 7 further including:
after selectively etching the hardmask layer and selectively etching the exposed first portions of the one or more outer semiconductor layers, removing remaining portions of the resist layer and the hardmask layer so as to expose second portions of the one or more outer semiconductor layers, wherein the second portions of the one or more outer semiconductor layers define optical meta-atoms of the metastructure.

9. The method of claim 7 wherein selectively etching the exposed first portions of the outer semiconductor film includes using an inductively coupled plasma, wherein remaining portions of the resist layer and the hardmask serve as a mask while etching the outer semiconductor film.

10. The method of claim 4, wherein the hardmask material is composed of a material selected from a group consisting of one or more of: chrome, titanium, aluminum, silicon nitride and silicon dioxide.

11. The method of claim 1 including etching portions of the sequence of semiconductor layers that form the lower reflector, the active layer, and the upper reflector to form a mesa structure.

12. The method of claim 11 wherein the metastructure is formed prior to forming the mesa structure.

13. The method of claim 11 wherein the metastructure is formed after forming the mesa structure.

14. The method of claim 3 wherein forming a metastructure in the one or more outer semiconductor layers includes:
providing a hardmask layer on the one or more outer semiconductor layers;
depositing a resist layer on the hardmask layer;
pressing a surface of a tool into the resist layer, wherein the surface of the tool includes features that are imprinted into the resist layer; and
releasing the tool from the resist layer.

15. The method of claim 14 further including:
after releasing the tool form the resist layer, removing portions of a residual resist layer that is on the hardmask layer, so as to expose first portions of the hardmask layer.

16. The method of claim 14 wherein the portions of the residual resist layer are removed using a directional oxygen plasma.

17. The method of claim 14 further including:
selectively etching the hardmask layer to expose first portions of the one or more outer semiconductor layers; and
selectively etching the exposed first portions of the one or more outer semiconductor layers to form trenches therein.

18. The method of claim 17 further including:
after selectively etching the hardmask layer and selectively etching the exposed first portions of the one or more outer semiconductor layers, removing remaining portions of the resist layer and the hardmask layer so as to expose second portions of the one or more outer semiconductor layers, wherein the second portions of the one or more outer semiconductor layers define optical meta-atoms of the metastructure.

19. The method of claim 17 wherein selectively etching the exposed first portions of the outer semiconductor film includes using an inductively coupled plasma, wherein remaining portions of the resist layer and the hardmask serve as a mask while etching the outer semiconductor film.

20. The method of claim 14 wherein the hardmask material is composed of a material selected from a group consisting of one or more of: chrome, titanium, aluminum, silicon nitride and silicon dioxide.
